(19) United States
(12) Patent Application Publication
(10) Pub. No.: US 2011/0073037 A1
(43) Pub. Date: Mar. 31, 2011

(54) EPITAXIAL GROWTH SUSCEPTOR

(75) Inventor: Masato Ohnishi, Nishishirakawa (JP)

(73) Assignee: SHIN-ETSU HANDOTAI CO., LTD., Tokyo (JP)

(21) Appl. No.: 12/746,021

(22) PCT Filed: Dec. 5, 2008
(86) PCT No.: PCT/JP2008/003621

§ 371 Date: Jun. 3, 2010

(30) Foreign Application Priority Data
Dec. 28, 2007 (JP) 2007-340749

(51) Int. Cl. C23C 16/458

(52) U.S. Cl. 118/641

(57) ABSTRACT

An epitaxial growth susceptor having a pocket that horizontally supports a single-crystal substrate in an epitaxial growth apparatus in which the pocket has an outer peripheral region with which the single-crystal substrate comes into contact to be supported; and a central region that is surrounded by the outer peripheral region and does not come into contact with the single-crystal substrate, one or more through holes that pierce the epitaxial growth susceptor are formed in the central region of the pocket, and the outer peripheral region of the pocket has a tapered shape that is inclined with a tilt angle that is greater than 0° and less than 1° in such a manner that a depth increases toward the central region, and also has a horizontal width that is 3.3% or more of a diameter of the single-crystal substrate to be supported.

### TECHNICAL FIELD

The present invention relates to an epitaxial growth susceptor (which may be simply referred to as a susceptor hereinafter) configured to support a single-crystal substrate during epitaxial growth in an epitaxial growth apparatus that deposits an epitaxial layer on the single-crystal substrate.

### BACKGROUND ART

An epitaxial growth technology is a technology that performs vapor phase growth with respect to a single-crystal thin film layer utilized for manufacture of an integrated circuit such as a bipolar transistor or an MOSLSI, and it is a very important technology since a uniform single crystal thin film can be grown on a clean semiconductor single crystal substrate in accordance with a crystal orientation of the substrate or a precipitous impurity gradient of a junction having a large difference in a dopant concentration can be formed.

As apparatuses configured to effect such epitaxial growth, three types, i.e., a vertical type (a pancake type), a barrel type (a cylinder type), and a horizontal type are general. These growth apparatuses have the common basic principle. The growth apparatus is configured to include a reaction chamber having an epitaxial growth susceptor on which a single-crystal substrate is mounted therein, heating units formed of, e.g., a halogen lamp provided outside the reaction chamber, and others, and a vertical apparatus that processes wafers one by one is called a single-wafer processing epitaxial growth apparatus.

For example, this single-crystal processing epitaxial growth apparatus will now be explained with reference to FIG. 9. FIG. 9 is a schematic view showing an example of a conventionally utilized general single-wafer processing epitaxial growth apparatus (Japanese Unexamined Patent Publication (Kokai) No. 2004-319623).

This single-wafer processing epitaxial growth apparatus 101 has a reaction chamber 103 in which a single-crystal substrate 102 having an epitaxial layer deposited on a surface thereof is arranged, and a gas feed port 104 through which a raw material gas/carrier gas is introduced into the reaction chamber 103 and a gas exhaust port 105 through which the gas is exhausted are provided in the reaction chamber 103. Further, a susceptor 106 on which a single-crystal substrate 102 is mounted is provided in the reaction chamber 103. It is to be noted that an upper wall 107 of the reaction chamber 103 is formed of quartz glass.

Furthermore, heating units 108 such as a halogen lamp that heats the single-crystal substrate 102 is provided to at least the outside of the reaction chamber 103.

The susceptor 106 will now be further described. FIG. 10 show an outline of an example of a conventional susceptor. FIG. 10(A) is a plan view and FIG. 10(B) is a cross-sectional view in the range of a part of the susceptor.

As shown in FIG. 10, a pocket 110 is formed in the susceptor 106, the pocket 110 has an outer peripheral region 111 and a central region 112 surrounded by the outer peripheral region 111, and a step 113 is formed at a boundary between the outer peripheral region 111 and the central region 112.

The outer peripheral region 111 has a tapered shape so that the single-crystal substrate 102 that is to be subjected to epitaxial growth can come into contact with and supported on a surface thereof, but the central region 112 is formed at a deeper position than the outer peripheral region 111 via the step 113 to prevent the single-crystal substrate 102 from coming into contact therewith. Furthermore, through holes 114 for removal of a native oxide film on a back surface of the single-crystal substrate 102, prevention of halo formation, and others are formed in the central region 112.

When using the single-wafer processing epitaxial growth apparatus 101 including the conventional susceptor 106 depicted in FIG. 9 to form an epitaxial layer on the single-crystal substrate 102, the single-crystal substrate 102 is arranged in the pocket 110 of the susceptor 106, and the single-crystal substrate 102 is heated to a predetermined temperature by the heating units 108 while rotating the single-crystal substrate 102 by a support shaft 109 that supports the susceptor 106 and a non-illustrated rotation mechanism that rotates the support shaft 109 (makes the support shaft 109 rotate). Moreover, for example, if a silicon single crystal layer is epitaxially grown in the reaction chamber 103, this epitaxial growth is performed by supplying a predetermined flow rate of a raw material gas such as trichlorosilane diluted with a carrier gas such as hydrogen from the gas feed port 104 for a predetermined time.

As described above, an epitaxial substrate having the epitaxial layer deposited on the single-crystal substrate 102 can be obtained.

However, when the conventional susceptor 106 is utilized to support the single-crystal substrate 102 and perform the epitaxial growth, the raw material gas flows to the back surface of the single-crystal substrate 102 from the through holes 114 formed in the central region 112 of the susceptor 106, and deposition may occur on the back surface of the single-crystal substrate 102. Therefore, there was a problem that flatness of an outer peripheral portion of the epitaxial substrate was degraded.

### DISCLOSURE OF INVENTION

Thus, the present inventor keenly studied about a substrate after the epitaxial growth and thereby found out that remarkable deposition is locally observed on the outer peripheral side of a back surface of an epitaxial substrate in particular. Additionally, the inventor discovered that this deposition on the outer peripheral side of the back surface intensively occurs near a position at which the single-crystal substrate comes into contact with the outer peripheral region of the pocket of the susceptor (a portion where the single-crystal substrate overlaps a horizontal width of the outer peripheral region of the pocket) and a local change in thickness thereby arises on the outer peripheral side of the epitaxial substrate. FIG. 10(B) also shows a deposition layer that is locally deposited on the outer peripheral side of the back surface of the single-crystal substrate. Although depending on a reaction time, a thickness of this deposition layer is approximately 0.05 to 0.3 μm.

It is an object of the present invention to provide an epitaxial growth susceptor that can prevent significant deposition from being locally produced on an outer peripheral side of a back surface of a single-crystal substrate.

To achieve the objet, the present invention provides an epitaxial growth susceptor having a pocket that horizontally supports a single-crystal substrate in an epitaxial growth apparatus, wherein the pocket has an outer peripheral region with which the single-crystal substrate comes into contact to be supported; and a central region that is surrounded by the outer peripheral region and does not come into contact with the single-crystal substrate, one or more through holes that pierce the epitaxial growth susceptor are formed in the central region of the pocket, and the outer peripheral region of the pocket has a tapered shape that is inclined with a tilt angle that is greater than 0° and less than 1° in such a manner that a depth increases toward the central region, and also has a horizontal width that is 3.3% or more of a diameter of the single-crystal substrate to be supported.

First, the present inventor conducted examination and thereby found out that reducing the tilt angle of the outer peripheral region of the pocket in the susceptor, expanding the outer peripheral region beyond that in a conventional product, and expanding a portion where the single-crystal substrate overlaps the outer peripheral region of the pocket in the susceptor so that deposition on the back surface of the single-crystal substrate can be gradually and continuously produced from the side closer to the central side of the single-crystal substrate is effective to prevent the local deposition on the outer peripheral side of the back surface of the single-crystal substrate.

That is, like the present invention, if there is provided the susceptor with which the single-crystal substrate comes into contact to be supported and which has the tapered outer peripheral region having the tilt angle that is greater than 0° and smaller than 1° and having the horizontal width that is equal to or above 3.3% of the diameter of the supported single crystal substrate, locally thick deposition can be prevented from being produced on the outer peripheral side of the back surface of the single-crystal substrate as different from the conventional products. Therefore, a high-quality epitaxial substrate having excellent flatness of the outer peripheral portion of the epitaxial substrate can be obtained.

Further, since one or more through holes that pierce the epitaxial growth susceptor are formed at the central region of the pocket, the native oxide film on the back surface of the single-crystal substrate can be effectively removed.

Furthermore, since the outer peripheral region of the pocket has the tapered shape that is inclined so that the depth increases toward the central region at the tilt angle greater than 0°, the inner edge of the outer peripheral region does not come into contact with the back surface of the single-crystal substrate, and therefore the back surface of the single-crystal substrate can be prevented from being scratched. Moreover, deposition on the outer peripheral side of the back surface can be suppressed because of the tilt angle that is less than 1°.

At this time, it is particularly preferable that the horizontal width of the outer peripheral region corresponding to a range from the central region to the outermost peripheral portion of the single-crystal substrate supported on the outer peripheral region is equal to or above 3.3% of the diameter of the single-crystal substrate.

Such a configuration enables assuredly preventing locally thick deposition from being produced on the outer peripheral side of the back surface of the single-crystal substrate.

At this time, it is preferable that the central region of the pocket has a concave shape formed of a curved surface.

The single-crystal substrate to be supported is apt to bend due to its own weight and, in this case, the single-crystal substrate may come into contact with the central region of the pocket, and a damage such as scratch or slip may be extended in the back surface of the single-crystal substrate.

However, when the central region of the pocket has the concave shape formed of the curved surface, the single-crystal substrate does not come into contact with the central region of the pocket even if the single-crystal substrate bends, thereby excellently maintaining the state of the back surface of the single-crystal substrate.

Moreover, it is preferable that the horizontal width of the outer peripheral region of the pocket is equal to or above 5.5% and equal to or below 7% of the diameter of the single-crystal substrate to be supported.

If the horizontal width of the outer peripheral region of the pocket is equal to or above 5.5% of the diameter of the single-crystal substrate to be supported as described above, the local deposition on the outer peripheral side of the back surface of the single-crystal substrate can be sufficiently prevented. Additionally, if this horizontal width is equal to or below 7%, the width of the outer peripheral region is not increased beyond necessity, i.e., the central region having the through holes formed therein can be assured with a sufficient size, thus efficiently removing the native oxide film on the back surface of the single-crystal substrate.

Further, it is preferable that the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

Such a configuration enables further effectively preventing the local deposition and removing the native oxide film on the back surface of the single-crystal substrate.

Furthermore, it is possible that the epitaxial growth susceptor is for a single-crystal substrate having a diameter of 300 mm or above.

Such a susceptor can be effectively utilized when performing epitaxial growth with respect to a single-crystal substrate having a diameter of 300 mm or above in response to a recent increase in diameter of the single-crystal substrate.

It is preferable that, in the pocket, a depth of an inner edge of the outer peripheral region coincides with a depth of an outer edge of the central region, or a step having a height that is less than 0.05 mm is formed in such a manner that the depth increases from the inner edge of the outer peripheral region toward the outer edge of the central region.

If such a configuration is adopted, a precipitous change in a depth direction from the outer peripheral region toward the central region of the pocket does not occur, and degradation in nanotopology of the back surface of the single-crystal substrate due to this precipitous change in the depth direction can be prevented.

When the epitaxial growth susceptor according to the present invention is adopted, the native oxide film on the back surface of the single-crystal substrate can be effectively removed during epitaxial growth, and generation of local significant deposition can be greatly suppressed on the outer peripheral side of the back surface of the single-crystal substrate, thereby obtaining the epitaxial substrate having excellent flatness of the outer peripheral portion.

### BRIEF DESCRIPTION OF DRAWINGS

FIG. 1 are schematic views showing an example of a susceptor according to the present invention, where (A) is a plan view, (B) is a cross-sectional view, and (C) is a cross-sectional view showing an example of another susceptor according to the present invention;

FIG. 2 are schematic views, where (A) shows an example of a susceptor according to the present invention having a flat central region and (B) shows an example of a susceptor according to the present invention having a concave central region having a curved surface;

FIG. 3 is a schematic view showing an example of single-wafer processing epitaxial growth apparatus including a susceptor according to the present invention;

FIG. 4 shows a result representing a relationship between a susceptor shape and a back surface ZDD value in each of Example and Comparative Example;

FIG. 5 is a graph showing an example of a relationship between an outer portion that is more than 120 mm from the center of a substrate in a radial direction and a back surface ZDD value in Example;

FIG. 6 is a graph showing an example of a result obtained by measuring a back surface ZDD value at a position that is 148 mm from the center in a radial direction on an entire circumference of a substrate in a circumferential direction in Example;

FIG. 7 is a graph showing an example of a relationship between an outer portion that is more than 120 mm from the center of a substrate in a radial direction and a back surface ZDD value in Comparative Example;

FIG. 8 is a graph showing an example of a result obtained by measuring a back surface ZDD value at a position that is 148 mm from the center in a radial direction on an entire circumference of a substrate in a circumferential direction in Comparative Example;

FIG. 9 is a schematic view showing an example of a general conventional single-wafer processing epitaxial growth apparatus; and

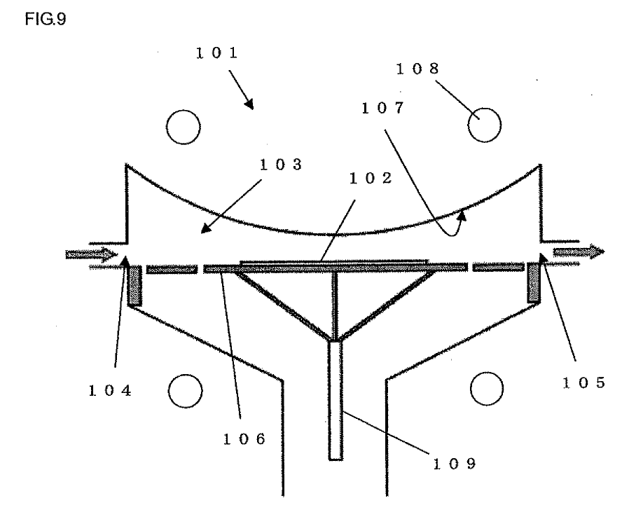

FIG. 10 are schematic views showing an example of a conventional susceptor, where (A) is a plan view and (B) is a cross-sectional view.

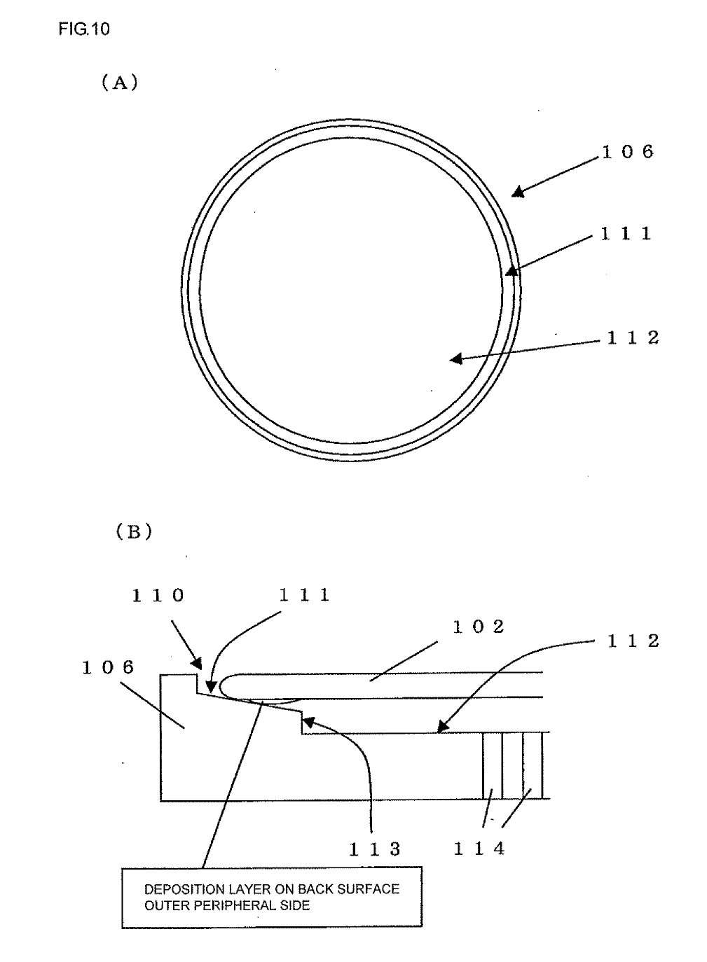

### BEST MODES FOR CARRYING OUT THE INVENTION

Although an embodiment according to the present invention will now be described hereinafter, the present invention is not restricted thereto.

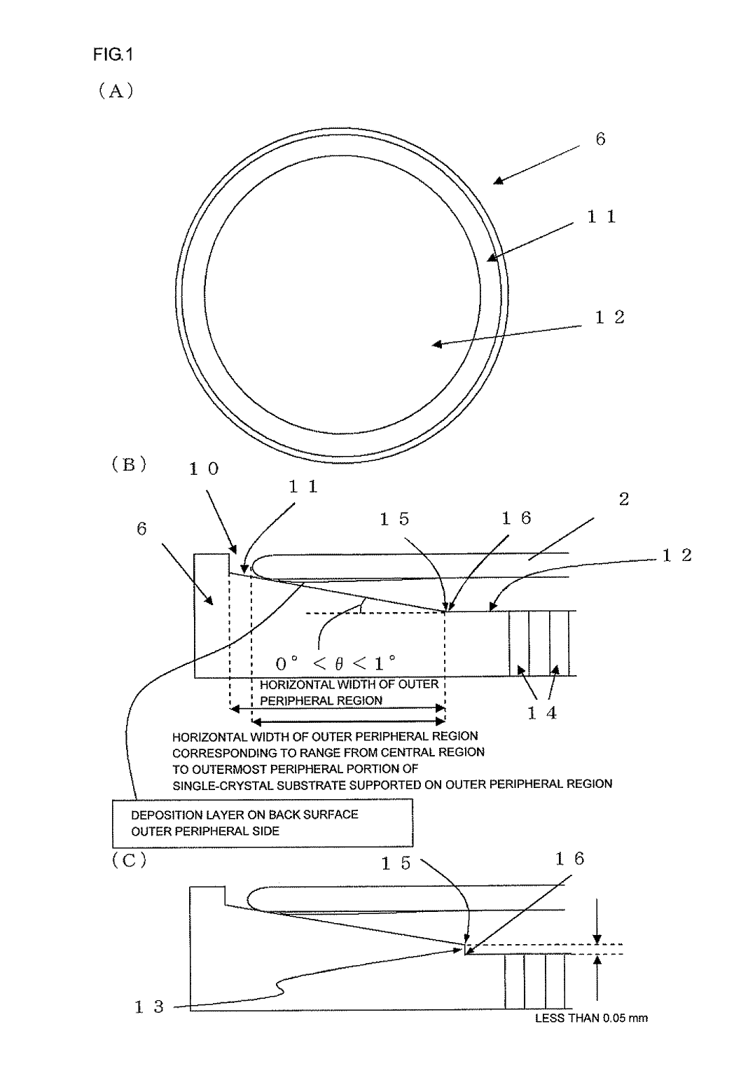

FIG. 1 show an outline of an example of an epitaxial growth susceptor according to the present invention. FIG. 1(A) is a plan view, and FIG. 1(B) is a cross-sectional view in the range of a part of the susceptor. Further, FIG. 1(C) is a cross-sectional view in the range of a part of another susceptor.

As shown in FIG. 1, first, a pocket 10 that accommodates a single-crystal substrate 2 and horizontally supports the same is formed in a susceptor 6 according to the present invention. Furthermore, this pocket 10 has an outer peripheral region 11 and a central region 12 surrounded by the outer peripheral region 11.

The outer peripheral region 11 has a tapered shape, and the single-crystal substrate 2 that is to be subjected to epitaxial growth comes into contact with and horizontally supported on this outer peripheral region. On the other hand, the central region 12 is formed at a position deeper than that of the outer peripheral region 11 so as to prevent the single-crystal substrate 2 from coming into contact with the outer peripheral region 11.

The central region 12 will now be described. Through holes 14 that pierce the susceptor 6 are formed in this central region 12. The number of the through holes 14 is not restricted in particular, forming one or more through holes can suffice, but forming many through holes in the entire surface of the central region 12 is preferable. When the through holes are formed in the entire surface of the central region 12, a native oxide film on a back surface of the single-crystal substrate 2 can be removed from the entire back surface at the time of epitaxial growth, thereby preventing halo formation.

It is to be noted that a cross-sectional shape, a size, and others of the through hole 14 are not restricted in particular, and they can be appropriately determined each time. They can be equal to those in conventional products, for example.

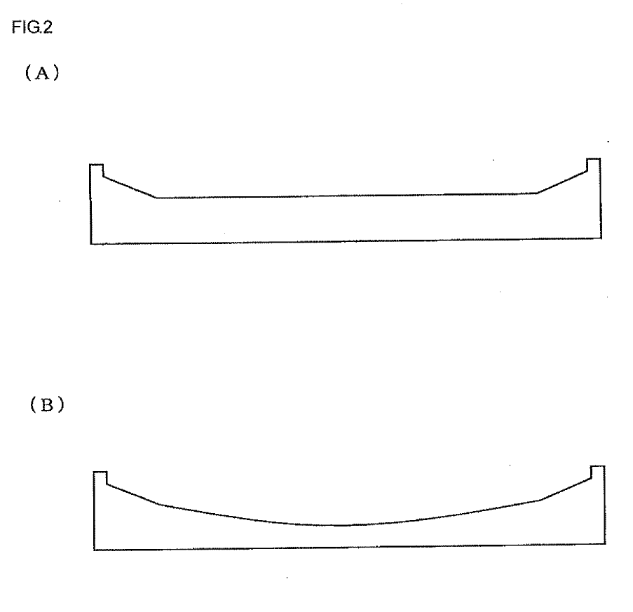

Moreover, a shape (a plane shape) of the central region 12 is not restricted in particular as long as it is not in contact with the single-crystal substrate 2 that comes into contact with the outer peripheral region 11 to be supported. For example, a flat shape can be adopted. FIG. 2(A) shows an example when the central region 12 is flat.

However, when the single-crystal substrate 2 is supported on the outer peripheral region 11, the central side of the single-crystal substrate 2 is apt to bend downwards due to its own weight in reality. Considering such a situation, it is preferable for the central region 12 to have a concave shape formed of a curved surface as shown in FIG. 2(B).

When such a configuration is adopted, even if the single-crystal substrate 2 bends, the central region 12 of the pocket 10 in the susceptor 6 does not come into contact with the single-crystal substrate 2, thereby excellently maintain a state of the back surface of the single-crystal substrate 2.

The outer peripheral region 11 will now be described. As shown in FIG. 1(B), the outer peripheral region 11 has a tapered shape inclined at a tilt angle θ that is greater than 0° and less than 1°, and it is formed so that its depth can increase toward the central region 12. When supporting the single-crystal substrate 2, the outer peripheral region 11 comes into contact with an outer peripheral portion of a back surface of the single-crystal substrate 2.

Here, when the tilt angle θ is equal to or below 0°, an inner edge 15 of the outer peripheral region 11 comes into contact with the back surface of the single-crystal substrate 2, a scratch is produced on the back surface of the single-crystal substrate 2. On the other hand, when the tilt angle θ is equal to or above 1°, local deposition (e.g., deposition of silicon when using trichlorosilane for a raw material gas) is produced on the back surface outer peripheral side of the single-crystal substrate 2. Therefore, to prevent these productions, the tilt angle θ must be set to a value that is greater than 0° and less than 1°.

Additionally, a horizontal width of this outer peripheral region 11 is equal to or above 3.3% of a diameter of the single-crystal substrate 2. In a conventional product, a horizontal width of the outer peripheral region 11 is approximately 1%, a range where the single-crystal substrate 2 and the outer peripheral region 11 overlap is narrow, and hence locally thick deposition is produced on the outer peripheral side of the back surface of the single-crystal substrate 2, whereby flatness of an outer peripheral portion of an epitaxial substrate is adversely affected.

However, like the present invention, when the range of the horizontal width is larger than that in the conventional product, the range where the single-crystal substrate 2 and the outer peripheral region 11 overlap is increased, and hence the deposition on the back surface of the single-crystal substrate 2 can be gradually and continuously produced from the side close to the center of the single-crystal substrate 2 (see FIG. 1(B)), thereby the locally thick deposition as conventional examples is not produced and a precipitous change in thickness does not occur on the outer peripheral side.

The horizontal width of the outer peripheral region 11 that is equal to or above 3.3% of the diameter of the single-crystal substrate 2 can suffice, and its upper limit and others are not restricted as long as the central region can be assured, but the horizontal width that is equal to or above 5.5% and less than 7% is particularly preferable. When the horizontal width falls within such a range, local deposition on the outer peripheral side of the single-crystal substrate can be very effectively suppressed, and the range of the central region 12 can be also sufficiently assured. If the range of the central region 12 can be sufficiently assured, a native oxide film can be removed and halo formation can be prevented over the extensive range of the back surface of the single-crystal substrate 2 in concert with the effect provided by the through holes 14.

Further, in the horizontal direction in particular, it is preferable for the horizontal width of the outer peripheral region 11 corresponding to the range from the central region 12 to the outermost peripheral portion of the single-crystal substrate 2 supported on the outer peripheral region 11 to be a width that is 3.3% or more or a width that is equal to or above 5.5% and equal to or below 7% of the diameter of the single-crystal substrate 2. When such a configuration is adopted, the range where the single-crystal substrate 2 and the outer peripheral region 11 overlap can be assuredly increased as compared with that in the conventional example, thereby further assuredly suppressing local deposition.

It is to be noted that a gap (clearance) between the outer edge of the outer peripheral region 11 and the outermost peripheral portion of the supported single-crystal substrate 2 is usually very small. In general, a configuration adapted to a size of the single-crystal substrate 2 processed by the pocket of the susceptor is practically adopted in terms of productivity and others.

Furthermore, giving a description on a boundary between the outer peripheral region 11 and the central region 12, it is preferable that a depth of the inner edge 15 of the outer peripheral region coincides with that of the outer edge 16 of the central region as shown in FIG. 1(B) or that a step 13 having a height that is less than 0.05 mm is formed in such a manner that the depth increases from the inner edge 15 of the outer peripheral region toward the outer edge 16 of the central region as shown in FIG. 1(C). That is, it is preferable that a change in the depth direction from the outer peripheral region 11 toward the central region 12 is suppressed to be less than 0.05 mm.

When the tilt angle of the outer peripheral region 11 is less than 1° like the present invention, it is possible to effectively prevent nanotopology from being degraded due to displacement produced at a portion corresponding to the boundary between the outer peripheral region 11 and the central region 12 of the pocket 10 on the back surface of the single-crystal substrate 2 at the time of epitaxial growth by suppressing the change in depth direction from the outer peripheral region 11 toward the central region 12 to be less than 0.05 mm.

It is to be noted that if the step 13 having the height that is less than 0.05 mm is formed in such a manner that the depth increases from the inner edge 15 of the outer peripheral region toward the outer edge 16 of the central region as depicted in FIG. 1(C), the through holes 14 in the central region 12 can be relatively distanced from the back surface of the single-crystal substrate 2, thereby effectively preventing transference associated with the through holes 14 from being formed on the back surface of the single-crystal substrate 2.

Furthermore, the susceptor 6 according to the present invention can be compatible with various kinds of single-crystal substrates 2 and, for example, a size of the susceptor 6 itself can be matched with a size of the single-crystal substrate 2 to be supported. Of course, the susceptor can be compatible with a single-crystal substrate having a diameter of 300 mm or above, and it can be used for manufacturing epitaxial substrates each having a large diameter in association with a recent demand.

Besides, a material and others of the susceptor 6 itself are not restricted in particular, and the susceptor 6 can be formed of an appropriate material in dependence upon, e.g., a single-crystal substrate to be supported. For example, there is a susceptor obtained by coating a graphite base material with SiC.

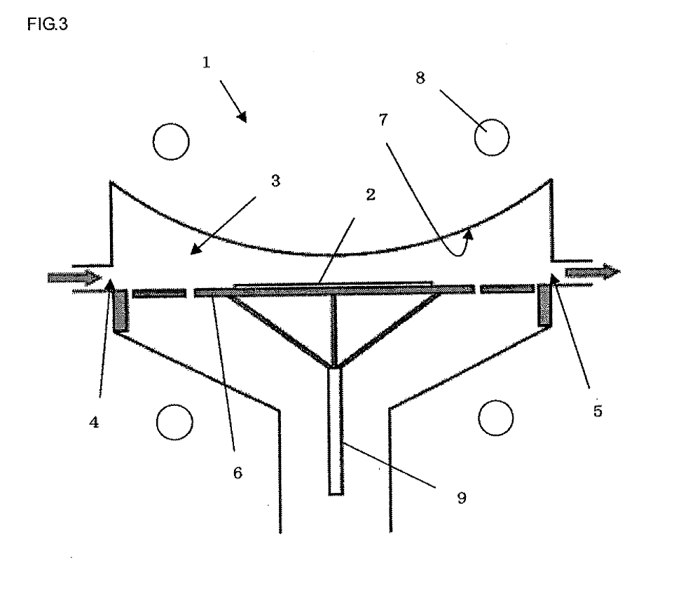

Moreover, when the single-crystal substrate 2 is supported and subjected to the epitaxial growth by using the above-described susceptor 6 according to the present invention, the susceptor 6 can be arranged in such a single-wafer processing epitaxial growth apparatus 1 as depicted in FIG. 3 to perform processing.

In this epitaxial growth apparatus 1, a reaction chamber 3, a gas feed port 4, a gas exhaust port 5, an upper wall 7, heating units 8, a support shaft 9, and others except the susceptor 6 according to the present invention are not restricted in particular, and the members equal to those in the conventional example can be utilized. Additionally, the procedure for effecting the epitaxial growth itself can be carried out by the same method as those in the conventional example.

Although the present invention will now be explained in more detail based on examples, the present invention is not restricted thereto.

### EXAMPLE

A single-wafer processing epitaxial growth apparatus depicted in FIG. 3 including the susceptor according to the present invention was utilized to perform epitaxial growth with respect to a single-crystal substrate, and then a deposition layer on a back surface of an obtained epitaxial substrate was evaluated.

A silicon single crystal substrate having a diameter of 300 mm was prepared as a single-crystal substrate, trichlorosilane was used as a raw material gas, and a hydrogen gas was utilized as a carrier gas.

As a susceptor, there was prepared one having a configuration that a plurality of through holes are formed in an entire surface of a central region having a concave shape formed of a curved surface without a step, a tilt angle of an outer peripheral region is 0.5° or 0.75°, a horizontal width of the outer peripheral region is one of 3.4% (a horizontal width of the outer peripheral region/a diameter of a silicon single crystal substrate=0.034), 5.7% (0.057), and 6.7% (0.067) of a diameter of the prepared silicon single crystal substrate. It is to be noted that the horizontal width of the outer peripheral region corresponding to the range from the central region of the susceptor to the outermost peripheral portion of the single-crystal substrate was 3.1%, 5.4%, or 6.4% of a diameter of the single-crystal substrate, respectively.

Furthermore, in regard to evaluation of a grown thickness of the deposition layer on the back surface of the epitaxial substrate, an optical interference type flatness measuring instrument was utilized to apply a near-edge curvature geometry measuring method (a geometry parameter called “ZDD”) for performing second order differential with respect to a surface displacement amount with a radius. Since ZDD is second order differential of a radius vector, it represents an accelerated change in displacement amount of the back surface with respect to the radius.

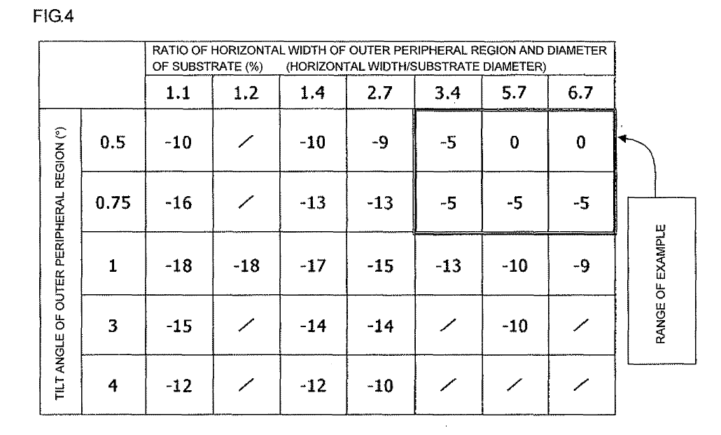

FIG. 4 shows a relationship between a susceptor shape and an obtained back surface ZDD value. It is to be noted that the back surface ZDD value in FIG. 4 is an example of a value at a position that is 148 mm from the center in a radial direction.

As described above, each value is suppressed to fall within the range of 0 nm/mm² to −5 nm/mm². It can be understood that an absolute value of the back surface ZDD value is smaller than that in a later-described comparative example and the deposition layer of silicon can be suppressed from significantly growing at the measurement position.

Moreover, in particular, the back surface ZDD value is 0 when the tilt angle is 0.5° and the horizontal width is 5.7% or 6.7%, and it can be understood that these cases are particularly excellent for preventing local precipitous deposition of silicon on the outer peripheral side of the back surface.

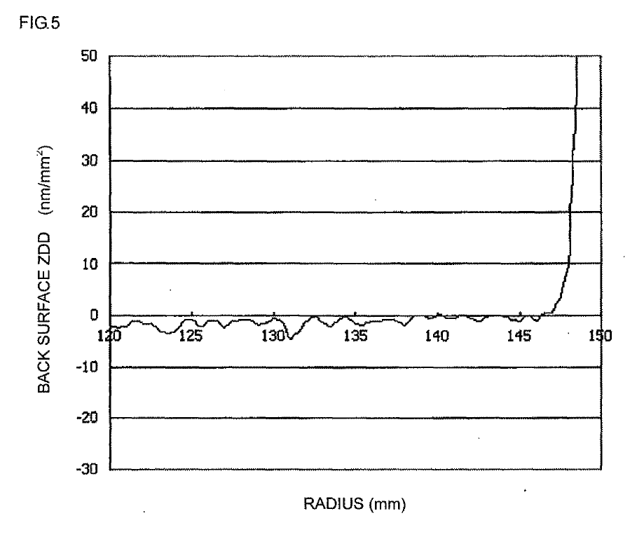

Additionally, FIG. 5 shows an example of a relationship between an outer portion that is more than 120 mm apart from the center of the substrate in the radial direction and the back surface ZDD value. This corresponds to an example using a susceptor having a tilt angle of 0.5° and a horizontal width of 5.7%. A degree of deposition in the radial direction of the substrate can be read from this drawing.

In FIG. 5, an abscissa represents a substrate radius (mm) and an ordinate represents ZDD (nm/mm²) of the back surface of the epitaxial substrate. As described above, the back surface ZDD represented by the ordinate corresponds to a result obtained by performing second order differential with respect to a surface displacement amount with a radius and indicates an accelerated change in displacement amount. Since this FIG. 5 relates to the back surface, a + direction represents displacement toward the front side of the substrate and a − direction represents displacement toward the back side of the substrate.

A fluctuation in back surface ZDD value was small even in the radius range of 145 nm to 148 nm where thick deposition was precipitously produced when a conventional susceptor was utilized, and a locally significant increase in thickness of the deposition layer was not observed.

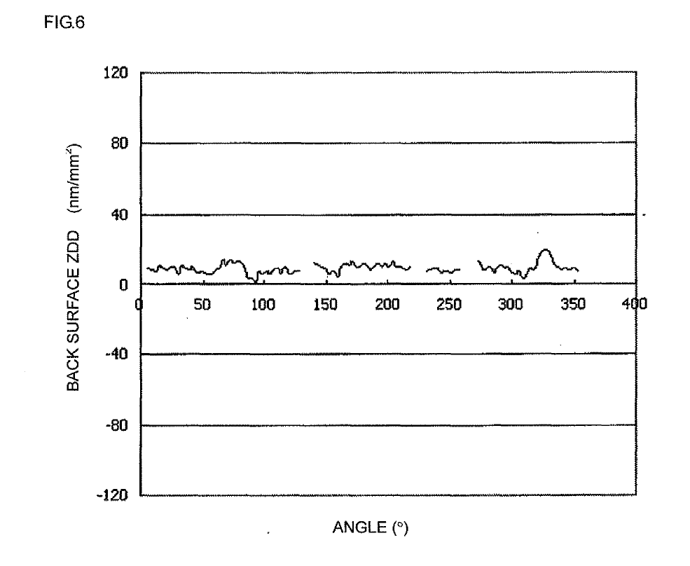

Further, FIG. 6 shows a result obtained by measuring the back surface ZDD value at a position that is 148 mm from the center in the radial direction on the entire circumference of the back surface of the substrate along the circumferential direction.

A position where the back surface ZDD value precipitously largely fluctuates was not observed on the entire circumference of the back surface of the substrate. That is, the deposition was not locally thickly deposited on the entire circumference of the back surface of the substrate, and the back surface having a uniform displacement amount was obtained.

These tendencies shown in FIGS. 5 and 6 were also observed in examples using another susceptor according to the present invention having different tilt angle and horizontal width.

### COMPARATIVE EXAMPLE

A single-wafer processing epitaxial growth apparatus that includes a susceptor having a tilt angle and a horizontal width of an outer peripheral region different from those in the present invention was utilized to perform epitaxial growth with respect to the same silicon single-crystal substrate as that in Example. Operating conditions except the susceptor are the same as those in Example.

It is to be noted that, as shown in FIG. 4, the tilt angle of the outer peripheral region in the range of 0.5° to 4° and the horizontal width of the same in the range of 1.1% to 6.7% (0.8% to 6.4% in case of a horizontal width of the outer peripheral region corresponding to the range from a central region of the susceptor to the outermost peripheral portion of the single-crystal substrate) were combined to carry out the operation. However, the combinations in the range according to the present invention were of course excluded.

Furthermore, examination about a deposition layer on a back surface was also conducted like Example.

FIG. 4 shows a relationship between a susceptor shape and an obtained back surface ZDD value like Example.

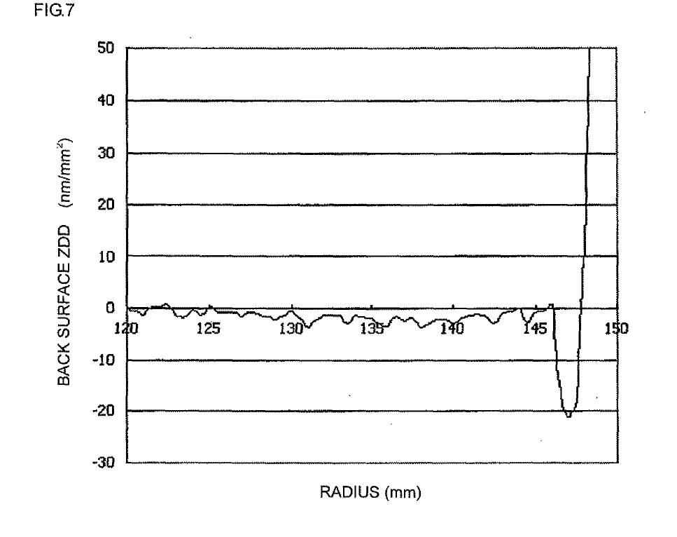

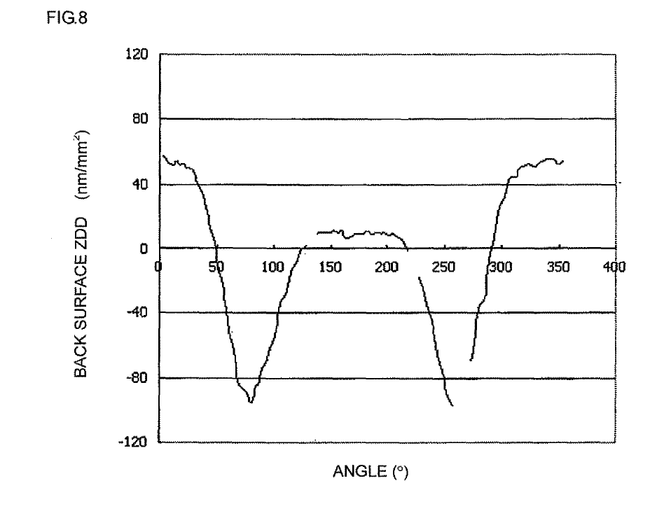

As depicted in FIG. 4, each value is −9 nm/mm² or below, and it can be understood that an absolute value of the back surface ZDD value is larger than that in Example and deposition precipitously grows at the measurement position. It can be also understood from FIGS. 7 and 8 that the deposition layer locally grows on the outer peripheral side of the substrate.

FIG. 7 is a graph showing an example of a relationship between an outer portion that is more than 120 mm apart from the center of the substrate in the radial direction and the back surface ZDD value when the tilt angle is 1° and the horizontal width is 1.1%. Moreover, FIG. 8 shows a result obtained by measuring the back surface ZDD value at each position that is 148 mm from the center in the radial direction on the entire circumference of the substrate in the circumferential direction.

As shown in FIG. 7, it can be understood that the back surface ZDD value locally greatly varied, i.e., the deposition layer precipitously thickly grew on the outer peripheral side (near 148 mm) of the substrate.

Additionally, as shown in FIG. 8, the back surface ZDD value greatly fluctuated in the circumferential direction, and it can be understood that the deposition layer was deposited with a non-uniform thickness. When deposition of silicon was non-uniformly carried out in this manner, flatness of the outer peripheral portion of the substrate is of course degraded.

As can be understood from Example and Comparative Example described above, locally significant deposition of silicon can be prevented on the outer peripheral side of the back surface of the single-crystal substrate that is to be subjected to epitaxial growth when the epitaxial growth susceptor according to the present invention is utilized. Therefore, the epitaxial substrate having excellent flatness of the outer peripheral portion can be obtained.

It is to be noted that the present invention is not restricted to the foregoing embodiment. The foregoing embodiment is just an exemplification, and any examples that have substantially the same configuration and demonstrate the same functions and effects as the technical concept described in claims of the present invention are included in the technical scope of the present invention.

1-7. (canceled)

8. An epitaxial growth susceptor having a pocket that horizontally supports a single-crystal substrate in an epitaxial growth apparatus,
wherein the pocket has
an outer peripheral region with which the single-crystal substrate comes into contact to be supported; and
a central region that is surrounded by the outer peripheral region and does not come into contact with the single-crystal substrate,
one or more through holes that pierce the epitaxial growth susceptor are formed in the central region of the pocket, and
the outer peripheral region of the pocket has a tapered shape that is inclined with a tilt angle that is greater than 0° and less than 1° in such a manner that a depth increases toward the central region, and also has a horizontal width that is 3.3% or more of a diameter of the single-crystal substrate to be supported.

9. The epitaxial growth susceptor according to claim 8, wherein the horizontal width of the outer peripheral region corresponding to a range from the central region to the outermost peripheral portion of the single-crystal substrate supported on the outer peripheral region is equal to or above 3.3% of the diameter of the single-crystal substrate.

10. The epitaxial growth susceptor according to claim 8, wherein the central region of the pocket has a concave shape formed of a curved surface.

11. The epitaxial growth susceptor according to claim 9, wherein the central region of the pocket has a concave shape formed of a curved surface.

12. The epitaxial growth susceptor according to claim 8, wherein the horizontal width of the outer peripheral region of the pocket is equal to or above 5.5% and equal to or below 7% of the diameter of the single-crystal substrate to be supported.

13. The epitaxial growth susceptor according to claim 9, wherein the horizontal width of the outer peripheral region of the pocket is equal to or above 5.5% and equal to or below 7% of the diameter of the single-crystal substrate to be supported.

14. The epitaxial growth susceptor according to claim 10, wherein the horizontal width of the outer peripheral region of the pocket is equal to or above 5.5% and equal to or below 7% of the diameter of the single-crystal substrate to be supported.

15. The epitaxial growth susceptor according to claim 11, wherein the horizontal width of the outer peripheral region of the pocket is equal to or above 5.5% and equal to or below 7% of the diameter of the single-crystal substrate to be supported.

16. The epitaxial growth susceptor according to claim 8, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

17. The epitaxial growth susceptor according to claim 9, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

18. The epitaxial growth susceptor according to claim 10, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

19. The epitaxial growth susceptor according to claim 11, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

20. The epitaxial growth susceptor according to claim 12, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

21. The epitaxial growth susceptor according to claim 13, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

22. The epitaxial growth susceptor according to claim 14, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

23. The epitaxial growth susceptor according to claim 15, wherein the horizontal width of the outer peripheral region corresponding to the range from the central region to the outermost peripheral portion of the single-crystal substrate supported on the outer peripheral region is equal to or above 5.5% and equal to or below 7% of the diameter of the single-crystal substrate.

24. The epitaxial growth susceptor according to claim 8, wherein the epitaxial growth susceptor is for a single-crystal substrate having a diameter of 300 mm or above.

25. The epitaxial growth susceptor according to claim 23, wherein the epitaxial growth susceptor is for a single-crystal substrate having a diameter of 300 mm or above.

26. The epitaxial growth susceptor according to claim 8, wherein, in the pocket, a depth of an inner edge of the outer peripheral region coincides with a depth of an outer edge of the central region, or a step having a height that is less than 0.05 mm is formed in such a manner that the depth increases from the inner edge of the outer peripheral region toward the outer edge of the central region.

27. The epitaxial growth susceptor according to claim 25, wherein, in the pocket, a depth of an inner edge of the outer peripheral region coincides with a depth of an outer edge of the central region, or a step having a height that is less than 0.05 mm is formed in such a manner that the depth increases from the inner edge of the outer peripheral region toward the outer edge of the central region.
